(19) United States
(12) Patent Application Publication
(10) Pub. No.: US 2005/0230709 A1
(43) Pub. Date: Oct. 20, 2005

(54) Semiconductor device

(76) Inventor: Ga Won Lee, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 10/879,978

(22) Filed: Jun. 29, 2004

(30) Foreign Application Priority Data
Apr. 19, 2004 (KR) 2004-26541

(51) Int. Cl. H01L 27/10

(52) U.S. Cl. 257/202

(57) ABSTRACT

A semiconductor device capable of suppressing leakage current increased due to an active moat generated when performing a shallow trench isolation process comprising an isolation layer is formed through a shallow trench isolation process in order to obtain a small isolation pitch; and a plurality of gates passing through an active region defined by the isolation layer, wherein at least one gate includes a sub-gate formed at a lateral side of the gate adjacent to a boundary formed between the active region and the isolation layer and having a length longer than lengths of other parts of the gate. Optionally the length of the sub-gate is about double the length of the remaining portion of the gate.

### BACKGROUND OF THE INVENTION

1. Field of the Invention

The present invention relates generally to a semiconductor device, and more particularly to a semiconductor device capable of suppressing leakage current which may experience an increase due to an active moat generated when performing a shallow trench isolation process.

2. Description of the Background Art

Currently, as semiconductor devices have been become more highly integrated, a conventional LOCOS (local oxidation of silicon) process has been replaced with an STI (shallow trench isolation) process for fabricating high-density semiconductor devices having small isolation pitches.

In the case of the LOCOS process, the size of an active region is reduced because a bird's-beak phenomenon occurs at an edge of an upper end of an isolation layer. However, in the case of the STI process, the size of the active region is sufficiently ensured because the isolation layer can be formed with a small width, so that high integration devices can be obtained.

Accordingly, the STI process has been essentially required in order to provide a minimum isolation pitch, a better planar surface or enhanced latch-up immunity.

Meanwhile, when carrying out the STI process for conventional semiconductor devices, as shown in FIGS. 1 and 2, a moat 20 (hereinafter, referred to as an “active moat”) occurs at the edge of an active region 12 adjacent to an isolation layer 10, thereby reducing the desirable properties of devices.

For example, if a voltage is applied to a gate 14 of a device in which an active moat 20 has been created, a strong fringe-field may be applied to the active moat 20, so that a turn-on path is easily formed. Therefore, the operational characteristics of the transistor are changed. In particular, in contrast with the current tendency for reducing the size of cell transistors in order to produce lower-priced and competitive DRAMs, INWE (inverse narrow width effect) may occur in cell transistors of DRAMs, especially those manufactured using the STI process, due to the active moat 20, so that leakage current increases in the sub threshold region and the off region of the transistor. Thus, the refresh characteristic of DRAMs is lowered.

In FIG. 2, reference numeral 13 represents a gate oxide layer.

Meanwhile, in order to suppress the characteristics produced by INWE, a method for increasing doping density of a substrate may be employed. However, use of such a method causes an increase in junction leakage current, so that the refresh characteristic of the DRAMs is lowered, as described above.

As a result, the semiconductor manufacturing method employing the STI process may increase leakage current due to the presence of the active moat.

### SUMMARY OF THE INVENTION

Accordingly, the present invention has been made to solve the above-mentioned problems occurring in the prior art, and a first object of the present invention is to provide a method of fabricating a semiconductor device capable of suppressing leakage current increases due to an active moat from occurring when performing a shallow trench isolation process.

A second object of the present invention is to provide a method for fabricating a semiconductor device capable of ensuring a refresh characteristic by suppressing leakage current increases due to an active moat.

In order to accomplish these objects, there is provided a semiconductor device comprising an isolation layer formed by using a shallow trench isolation process providing for a small isolation pitch; and a plurality of gates passing through an active region defined by the isolation layer, wherein at least one gate includes a sub-gate formed at a lateral side of the gate adjacent to a boundary between the active region and the isolation layer, wherein the sub-gate has a length longer than lengths of the remaining parts of the gate.

Herein, the plurality of sub-gates are associated with the at least one gate, one sub-gate being formed at either lateral side of the gate adjacent to the boundary formed between the active region and the isolation layer.

The sub-gate is preferably selectively formed only at one lateral side of the gate adjacent to the boundary formed between the active region and the isolation layer. In this case, the sub-gate is selectively formed only at first lateral sides of neighboring gates, and the first sides face each other. Also, the sub-gate may be selectively formed at second lateral sides of neighboring gates, and the second sides do not face each other. In addition, the sub-gate may be selectively formed only at one portion of two longitudinal parts formed in gates, which are adjacent to each other, so that the sub-gate formed in one gate is opposite to the sub-gate formed in the other adjacent gate.

### BRIEF DESCRIPTION OF THE DRAWINGS

The above and other objects, features and advantages of the present invention will be more apparent from the following detailed description taken in conjunction with the accompanying drawings, in which:

FIGS. 1 and 2 are plan and cross-sectional views, respectively, illustrating a conventional shallow trench isolation (STI) structure;

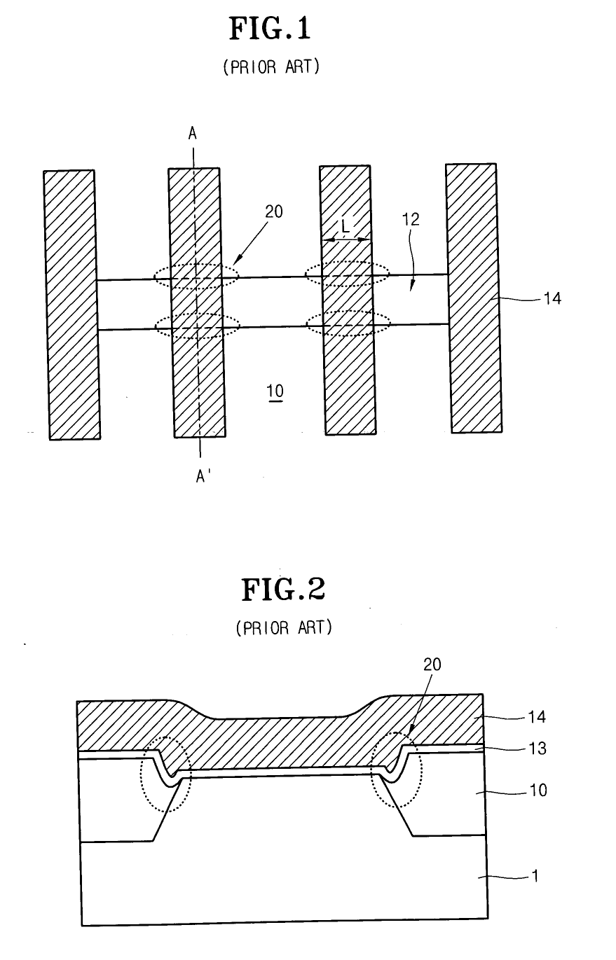

FIG. 3 is a plan view illustrating a semiconductor device according to one embodiment of the present invention; and

FIGS. 4a to 4c are plan views illustrating a semiconductor device according to other embodiments of the present invention.

### DETAILED DESCRIPTION OF THE PREFERRED EMBODIMENTS

Hereinafter, preferred embodiments of the present invention will be described with reference to the accompanying drawings. In the following description and drawings, the same reference numerals are used to designate the same or similar components, and so repetition of the description on the same or similar components will be omitted.

Hereinafter, a technical principle of the present invention will be described. According to the present invention, gates are designed such that the gates have a double length, thereby suppressing an increase of leakage current at an edge of an active region when performing a shallow trench isolation process.

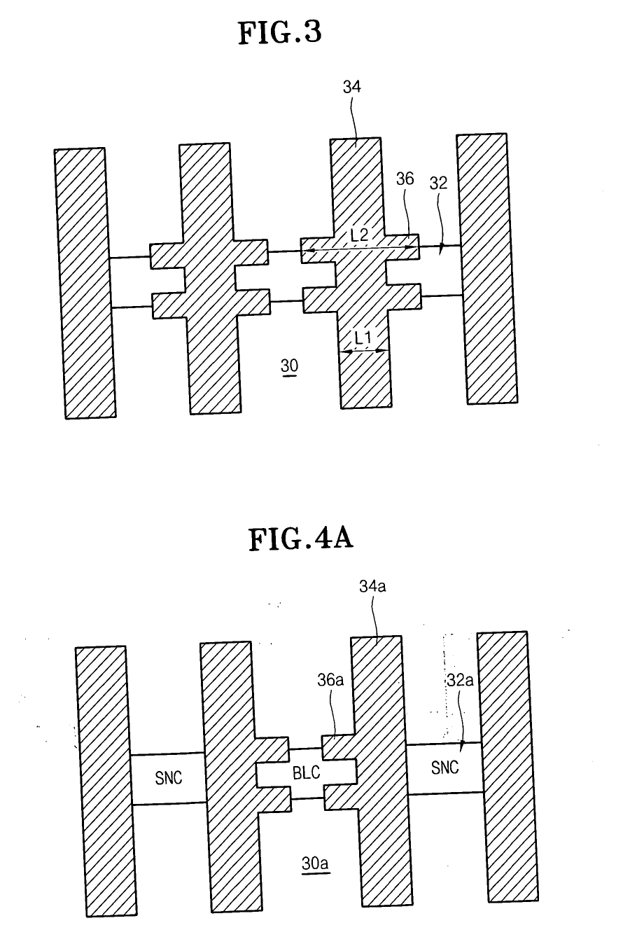

That is, as shown in FIG. 3, distinct from conventional transistors designed to have constant lengths, a gate 34 of the present invention is designed such that a first part of the gate 34, having length L2, which passes through a boundary between an active region (A/R) and an isolation layer 30, is relatively longer than the length L1 of a second part of the gate 34, which is the remainder of gate 34 except for the first part, which has the length L2.

In other words, in the present invention, the length L1 of the gate 34 is optimized according to a design rule and a sub-gate 36 is formed at both sides of the first part of the gate 34. The sub-gate 36 passes through the boundary between the active region (A/R) and the isolation layer 30, so that the first part, having a length L2 of the gate 34 in a boundary area, is partially increased, thereby allowing the gate to be formed with a length that is approximately double the length L1.

Herein, FIG. 3 illustrates in a plan view a semiconductor device according to one embodiment of the present invention. Reference numeral 30 represents a trench-type isolation layer formed through the STI process, reference numeral 32 represents the active region defined by the isolation layer, and reference numeral 34 represents a gate passing through the active region. Also, reference numeral 36 represents a sub-gate partially formed at the boundary between the active region 32 and the isolation layer 30. In addition, “L1” and “L2” represent the lengths of the gate 34 and the sub-gate 36, respectively, as set forth above.

A semiconductor device according to the present invention employing a sub-gate having a double length can suppress an increase of leakage current occurring at the edge of the active region when performing the STI process.

Generally, the short channel effect of transistors may occur as the length of a channel becomes reduced as a result of DIBL (drain induced barrier lowering), which occurs at the time the barrier is lowered when carriers are injected into a substrate from a source by drain voltage. Such a DIBL phenomenon may occur especially at the edge of an active region of an STI structure, which is subject to a strong fringe field. Accordingly, leakage current may seriously increase at a sub threshold region of the STI structure. However, according to the present invention, the length of a channel partially extends into the edge of the active region by designing the gate to have a double length L2, so the DIBL phenomenon at the edge of the active region can be prevented, thus reducing leakage current in the sub threshold region of a transistor.

As a result, the present invention can easily suppress the increase of leakage current because of the gate design having a double length, so that it is possible to ensure a stable refresh characteristic.

Although they are not specifically described, but are shown in the drawing figures, the remaining components forming a transistor, except for the gate and forming of a semiconductor device, such as a DRAM, are provided essentially identically to the components forming a typical DRAM, and thus are not further described herein.

Also, in the transistor employing a gate having a double length, the length of a channel, that is, the length L1 of a gate at the area excluding the edge of the active region is optimized according to a design rule. Therefore, a gate having a double length does not exert any detrimental influence on the otherwise normal operational characteristics of the transistor.

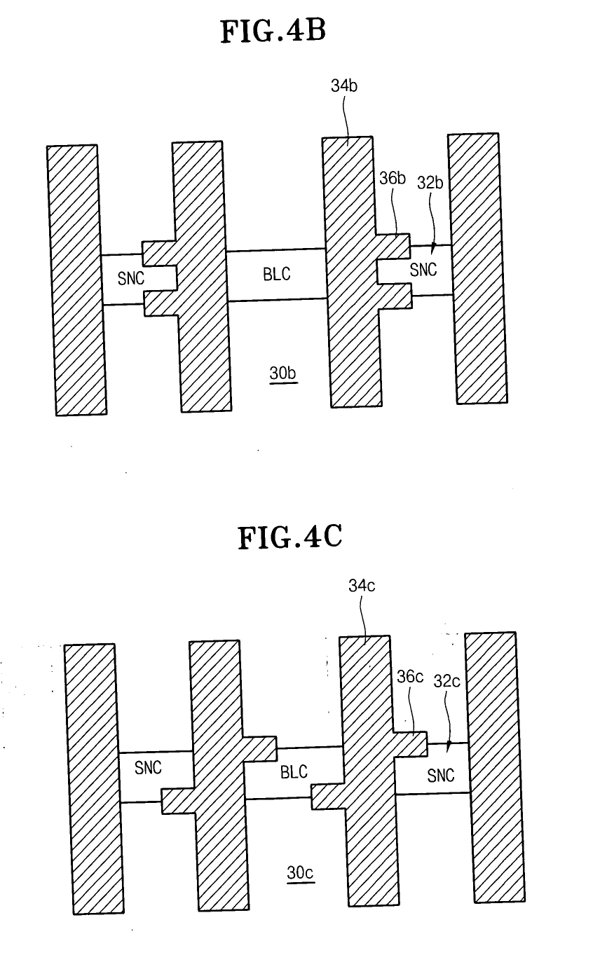

FIGS. 4A to 4c are plan views illustrating a semiconductor device according to other modified embodiments of the present invention.

According to another embodiment of the present invention, the sub-gate 36a, used for partially increasing the length of the gate, has various shapes that are configured differently from the sub-gate 36 according to the first embodiment of the present invention described above. Optimizing the size of each open area by considering properties such as contact resistance, that is, by considering SNC (storage node contact) and BLC (bit line contact) provides additional optimization criteria.

For example, as shown in FIG. 4A, the sub-gate 36a can selectively be installed only on a side of the gate 34a adjacent to a BLC area, so that the size of the SNC is maximized. In this case, sub-gates 36a of neighboring gates 34a face each other.

Also, as shown in another embodiment in FIG. 4B, the sub-gate 36b can selectively be installed only on a side of the gate 34b adjacent to an SNC area, so that the size of the BLC is maximized. In this case, sub-gates 36b of neighboring gates 34b do not oppose or face each other.

In addition, as shown in yet another embodiment in FIG. 4C, one sub-gate 36c can be formed in two parts of each of the gates 34c, which are opposite to each other, adjacent to the boundary formed between the active region 32c and the isolation layer 30c, so that the size of the SNC is identical to that of the BLC. In this case, alternate placement of the sub-gates 36′″ of neighboring gates 34′″ prevent the size of the open area from being reduced.

As described above, according to the present invention, it is possible to suppress leakage current increased due to an active moat occurring when performing an STI process or to compensate for leakage current by partially increasing the length of a channel on a boundary formed between an active region and an isolation layer through change of a gate design.

Accordingly, the present invention can prevent loss of cell current in a cell transistor of a DRAM, thereby improving the refresh characteristic. Therefore, it is possible to fabricate a DRAM having higher performance while enabling the continued trend toward higher integration and reduced sizes of semiconductor devices.

Although preferred embodiments of the present invention have been described for illustrative purposes, those skilled in the art will appreciate that various modifications, additions and substitutions are possible, without departing from the scope and spirit of the invention as defined in the accompanying claims.

1. A semiconductor device comprising;
an isolation layer formed by a shallow trench isolation process providing for a small isolation pitch; and
a plurality of gates passing through an active region defined by the isolation layer, wherein at least one gate includes a sub-gate formed at a lateral side of the gate adjacent to a boundary between the active region and the isolation layer, wherein the sub-gate has a length longer than lengths of the remaining parts of the gate.

2. The semiconductor device as claimed in claim 1, wherein a plurality of sub-gates are associated with at least one gate, one sub-gate being formed at either lateral side of the gate adjacent to the boundary formed between the active region and the isolation layer.

3. The semiconductor device as claimed in claim 1, wherein a plurality of sub-gates are associated with at least one gate, each sub-gate being selectively formed only on one lateral side of the gate adjacent to the boundary formed between the active region and the isolation layer.

4. The semiconductor device as claimed in claim 3, wherein a plurality of sub-gates are associated with at least one gate, each sub-gate being selectively formed only on first lateral sides of neighboring gates, wherein the first lateral sides face each other.

5. The semiconductor device as claimed in claim 3, wherein a plurality of sub-gates are associated with at least one gate, each sub-gate being selectively formed at second lateral sides of neighboring gates, wherein the second lateral sides do not face each other.

6. The semiconductor device as claimed in claim 3, wherein each sub-gate is selectively formed only at one longitudinal portion of two gates adjacent to each other, so that the sub-gate formed in one gate is in opposed relationship to the gate formed in the adjacent gate.

7. The semiconductor device as claimed in claim 1, wherein the length of each sub-gate is approximately double the length of the remaining parts of the gate.

8. The semiconductor device as claimed in claim 3, wherein the length of each sub-gate is approximately double the length of the remaining parts of the gate.

9. The semiconductor device as claimed in claim 4, wherein the length of each sub-gate is approximately double the length of the remaining parts of the gate.

10. The semiconductor device as claimed in claim 5, wherein the length of each sub-gate is approximately double the length of the remaining parts of the gate.

11. The semiconductor device as claimed in claim 6, wherein the length of each sub-gate is approximately double the length of the remaining parts of the gate.
